(19) United States
(12) Patent Application Publication
(10) Pub. No.: US 2024/0413078 A1
(43) Pub. Date: Dec. 12, 2024

(54) Anti-Fuse Device by Ferroelectric Characteristic

(71) Applicant: Nanya Technology Corporation, New Taipei City (TW)

(72) Inventor: YI-JU CHEN, Taipei City (TW)

(73) Assignee: Nanya Technology Corporation, New Taipei City (TW)

(21) Appl. No.: 18/207,309

(22) Filed: Jun. 8, 2023

(51) Int. Cl. H01L 23/525; H01L 29/51; H01L 29/78

(52) U.S. Cl. CPC H01L 23/5252; H01L 29/516; H01L 29/78391

(57) ABSTRACT

An anti-fuse device by ferroelectric characteristic is provided, which comprises an active area including a source region, a drain region laterally spaced from the source region and a channel between the source region and drain region, and a gate structure including a ferroelectric layer formed on the channel as well as a gate electrode formed on the ferroelectric layer. A programming operation of the anti-fuse device is performed by application of power to the gate electrode and at least one of the source region and drain region to cause a permanent electric field polarization in the ferroelectric layer to induce a conduction path along the channel. After the programming operation, the anti-fuse device will much easily turn on as the threshold voltage decreases even the operating voltage applied to the gate electrode is zero bias.

### BACKGROUND OF THE INVENTION

### Field of the Invention

The present invention relates to an anti-fuse device, and more particularly to an anti-fuse device performed by ferroelectric characteristic.

### Description of the Prior Art

For a semiconductor device, an anti-fuse repair technique is used to repair a bit fail occurring in an integrated chip, such as a DRAM. An anti-fuse device is an electrical device that performs the opposite function to a fuse. Traditional anti-fuse devices, for example NMOS anti-fuse device or PMOS anti-fuse device, use a gate oxide breakdown method to determine on or off state. The NMOS anti-fuse device has an NMOS transistor having a N-type doped polysilicon gate, a channel region, and source/drain regions formed by diffusion of N-type dopants in the silicon substrate. The channel region separates the source region from the drain region in the lateral direction, whereas a layer of dielectric material that prevents electrical current flow separates the polysilicon gate from the channel region. The PMOS anti-fuse device, similarly, the architecture is the same for the PMOS transistor, except a P-type dopant is used.

The dielectric material separating the polysilicon gate from the channel region, henceforth referred to as the gate oxide, usually consists of thermally grown silicon dioxide (SiO₂) material that leaks very little current through a mechanism, which is called Fowler-Nordheim tunneling under voltage stress. When stressed beyond a critical electrical field (applied voltage divided by the thickness of the gate oxide), the transistor is destroyed by rupturing of the gate oxide.

Rupturing gate oxide requires determining an appropriate pulse width duration and amplitude to limit power through the gate oxide, which produces a reliable, low resistance anti-fuse.

To perform an anti-fuse repair operation, the anti-fuse device is programmed by changing its electrical state to on state. FIG. 1A and FIG. 1B show a simplified view of the electric state changes of the anti-fuse programming using the gate oxide breakdown method. FIG. 1A shows the anti-fuse device 10 electrically connected to a repair circuit 100 has high resistance and is in the off state when the gate oxide is not breakdown. FIG. 1B shows the anti-fuse device 10 has low resistance and is in the on state when a gate oxide breakdown path generates. That is, when the anti-fuse device 10 blows out (i.e. the gate oxide breakdown) and generate a permanently conductive path, the anti-fuse device turns to low resistance, and the anti-fuse device is programmed.

In generally speaking, the anti-fuse device blows out depending on the gate oxide thickness or area. The process variation for manufacturing the anti-fuse device may change breakdown voltage that decrease anti-fuse blown out efficiency.

### SUMMARY OF THE INVENTION

The present invention provides an anti-fuse device by ferroelectric characteristic, in which a ferroelectric layer is provided and sandwiched between a gate electrode and a channel of a MOSFET structure. A channel conduction path is induced and established by a permanent electric field polarization caused in the ferroelectric layer after giving a plurality of voltage pulses at the gate electrode. A programming operation of the anti-fuse device may be performed by the natural ferroelectric characteristic instead of the gate oxide breakdown method. So, the drawback that the gate oxide breakdown voltage may change arising from process variation of the conventional anti-fuse device is avoidable.

In one embodiment, an anti-fuse device by ferroelectric characteristic of the present invention is configured as a MOSFET device structure comprises an active area having a source region, a drain region laterally spaced from the source region and a channel between the source region and drain region, and a gate structure having a ferroelectric layer formed on the channel and a gate electrode formed on the ferroelectric layer; wherein a programming operation of the anti-fuse device is performed by application of power to the gate electrode and at least one of the source region and drain region to cause a permanent electric field polarization in the ferroelectric layer to induce a conduction path along the channel. The MOSFET device would turn on much easily as a threshold voltage applied to the gate electrode decreases.

In an implementation of the present invention, the gate electrode is a metal gate electrode.

In an implementation of the present invention, the active area is a lightly doped well.

In an implementation of the present invention, the gate structure further comprises an interfacial layer sandwiched between the ferroelectric layer and the channel.

In an implementation of the present invention, the interfacial layer is a buffer layer.

In an implementation of the present invention, the source and drain regions are heavily doped with an N-type material.

In an implementation of the present invention, the source and drain regions are heavily doped with a P-type material.

In an implementation of the present invention, the programming operation of the anti-fuse device is performed by applying positive voltage pulses at the gate electrode with the source and drain region grounded.

In an implementation of the present invention, wherein the programming operation of the anti-fuse device is performed by applying negative voltage pulses at the gate electrode with the source and drain region grounded.

### BRIEF DESCRIPTION OF THE DRAWINGS

Other objects and advantages of the invention will become apparent upon reading the following detailed description and upon reference to the accompanying drawings in which:

FIG. 1A is a simplified view showing an anti-fuse device is in off state when a gate oxide of the anti-fuse device is not breakdown.

FIG. 1B is a simplified view showing the anti-fuse device is in on state when the gate oxide of the anti-fuse device is breakdown.

FIG. 2 is a schematic cross-sectional view of a FE NMOS anti-fuse device according to an embodiment of the present invention.

FIG. 3A is a schematic cross-sectional view of the FE NMOS anti-fuse device of FIG. 2 without any voltage bias, showing a ferroelectric layer of the FE NMOS anti-fuse device has random dipole directions.

FIG. 3B is a schematic cross-sectional view of the FE NMOS anti-fuse device of FIG. 2 applied a plurality of pulse gate voltage, showing all dipoles in the ferroelectric layer become stable and align in a consistent and constant direction.

FIG. 4 is a schematic cross-sectional view of the FE NMOS anti-fuse device of FIG. 2 after giving a plurality of positive pulse gate voltage, showing a conduction path along a channel of the FE NMOS anti-fuse device is induced by a permanent electric field polarization in ferroelectric layer.

FIG. 5 shows a diagram of drain current (ID) vs. gate voltage (VG) for the FE NMOS anti-fuse device of the present invention after a programming operation compared to a conventional NMOS anti-fuse device performed by the gate oxide breakdown method.

FIG. 6A is a schematic cross sectional view of a FE POMS anti-fuse device according to another embodiment of the present invention without any voltage bias, showing a ferroelectric layer of the FE PMOS anti-fuse device has random dipole directions.

FIG. 6B is a schematic cross-sectional view of the FE PMOS anti-fuse device applied a plurality of pulse gate voltage, showing all dipoles in the ferroelectric layer become stable and align in a consistent and constant direction.

FIG. 7 is a schematic cross-sectional view of the FE PMOS anti-fuse device after giving a plurality of positive pulse gate voltage, showing a conduction path along a channel of the FE PMOS anti-fuse device is induced by a permanent electric field polarization in ferroelectric layer.

FIG. 8 shows a diagram of drain current (ID) vs. gate voltage (VG) for the FE PMOS anti-fuse device of the present invention after a programming operation compared to a conventional PMOS anti-fuse device performed by the gate oxide breakdown method.

FIG. 9A shows an application of the FE NMOS anti-fuse device of FIG. 2.

FIG. 9B shows an application of the FE PMOS anti-fuse device of FIG. 6.

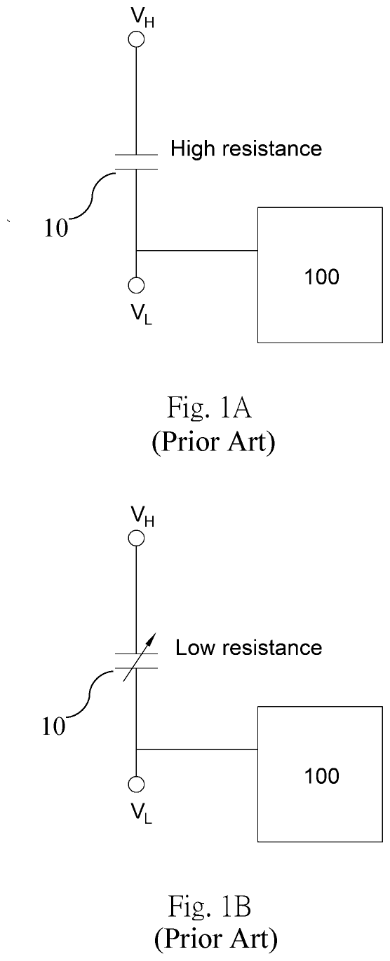

### DETAILED DESCRIPTION OF THE PREFERRED EMBODIMENTS

The present invention will now be described by way of preferred embodiments with references to the accompanying drawings. Like numerals refer to corresponding parts of various drawings. Please note well-known circuits, structures and techniques may not be shown in detail in order not to obscure the aspects of the disclosure. Various embodiments will be disclosed herein. However, it is to be understood that the disclosed embodiments are only used as an illustration that can be embodied in various forms. In addition, each of the examples given in connection with the various embodiments are intended to be illustrative but not limiting to. Further, the figures are not necessarily conform to the sizes and dimension ratios of actual structures, and some features are magnified to show details of particular components (and any dimensions, materials, and similar details shown in the figures are intended to be illustrative and not limiting to). Therefore, the particular structural and functional details are disclosed herein are not interpreted as limitations, but are used only to teach those skilled in the relevant field technicians to practice the basis of the disclosed embodiments.

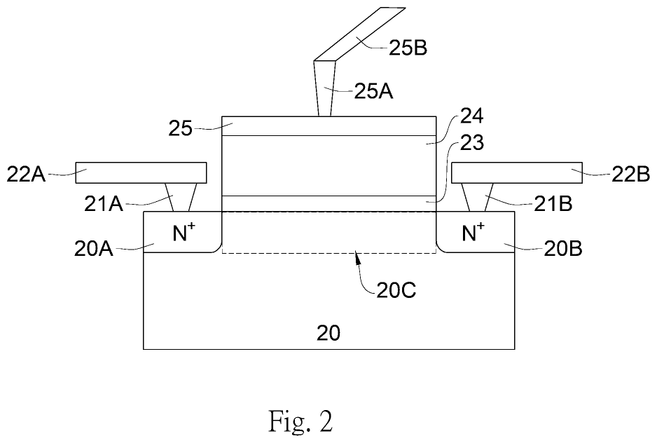

FIG. 2 is a schematic cross sectional view of an anti-fuse device configured as a ferroelectric NMOS (FE NMOS) structure according to an embodiment of the present invention. Hereinafter, the anti-fuse device is called the FE NMOS anti-fuse device, which comprises an active area 20 and a gate structure formed on the active area 20. The active area 20 has a source region 20A, a drain region 20B laterally spaced from the source region 20A and a channel 20C between the source region 20A and drain region 20B. The source and drain regions 20A, 20B are heavily doped with an N-type material. The gate structure has a ferroelectric layer 24 formed on the channel 20C and a gate electrode 25 formed on the ferroelectric layer 24. The gate structure further has an interfacial layer 23 sandwiched between the ferroelectric layer 24 and the channel 20C. In an implementation of the present invention, the gate electrode 25 may be a metal gate electrode due to the high dielectric constant of the ferroelectric layer 24. The active area 20 may be a lightly doped well, and the interfacial layer 23 may serve as a buffer layer to ease the formation of the ferroelectric layer 24 on the active area 20. The source region 20A may be applied a source voltage by a contact 21A and a metal line 22A. The drain region 20B may be applied a drain voltage by a contact 21B and a metal line 22B. An operating voltage of the FE NMOS anti-fuse device may be applied to the gate electrode 25 by a contact 25A and a metal line 25B.

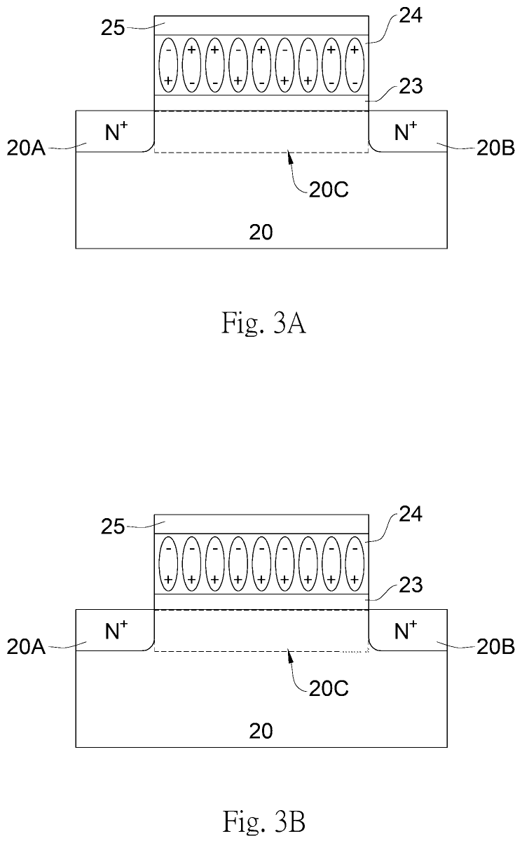

Please refer to FIG. 3A and FIG. 3B respectively illustrating the schematic cross sectional views of the FE NMOS anti-fuse device without any voltage bias and the FE NMOS anti-fuse device applied a pulse gate voltage. As shown in FIG. 3A, the ferroelectric layer 24 has random dipole directions without any voltage bias. After positive pulse amplitudes giving at the gate electrode 25, for example a positive pulse voltage of 1.5V is applied to the gate electrode 25, and the source/drain regions 20A, 20B are grounded, negative dipoles in the ferroelectric layer 24 turn directions toward the gate electrode 25 owing to positive bias from the gate electrode 25, whereas positive dipoles in the ferroelectric layer 24 turn directions toward the channel 20C. And, all the dipoles in the ferroelectric layer 24 become stable and align in a consistent and constant direction, as shown in FIG. 3B.

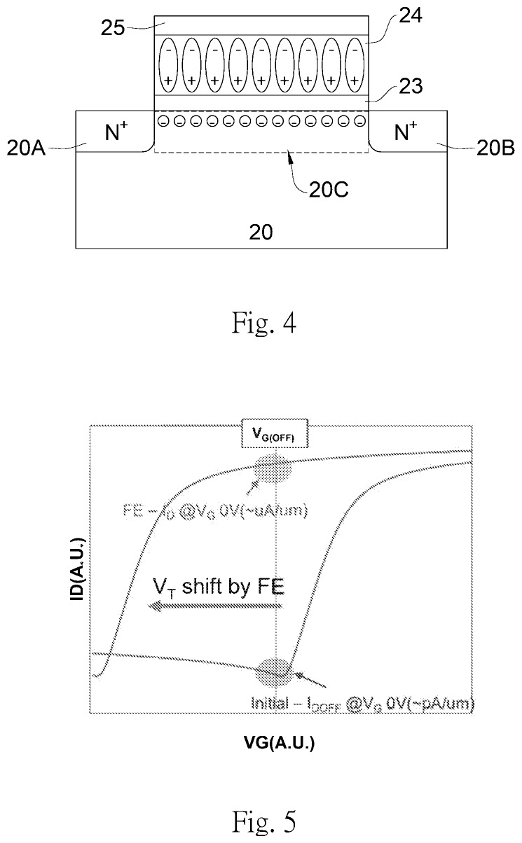

Please refer to FIG. 4, after giving the positive gate pulse voltage to the FE NMOS anti-fuse device, the dipoles in the ferroelectric layer 24 become stable and align in the consistent and constant direction, as such causing a permanent electric field polarization in the ferroelectric layer 24. A conduction path along the channel 20C is thus induced. So, the FE NMOS anti-fuse device turns on much easily as V_{T} (threshold voltage) decreases, even the gate electrode 25 is applied zero bias voltage.

FIG. 5 shows a diagram of drain current (ID) vs. gate voltage (VG) for the FE NMOS anti-fuse device of the present invention after the programming operation compared to the conventional NMOS anti-fuse device performed by the gate oxide breakdown method. The FE NMOS anti-fuse device of the present invention has a high drain current (I_{D}) even at a zero bias gate voltage (V_{G}˜0V).

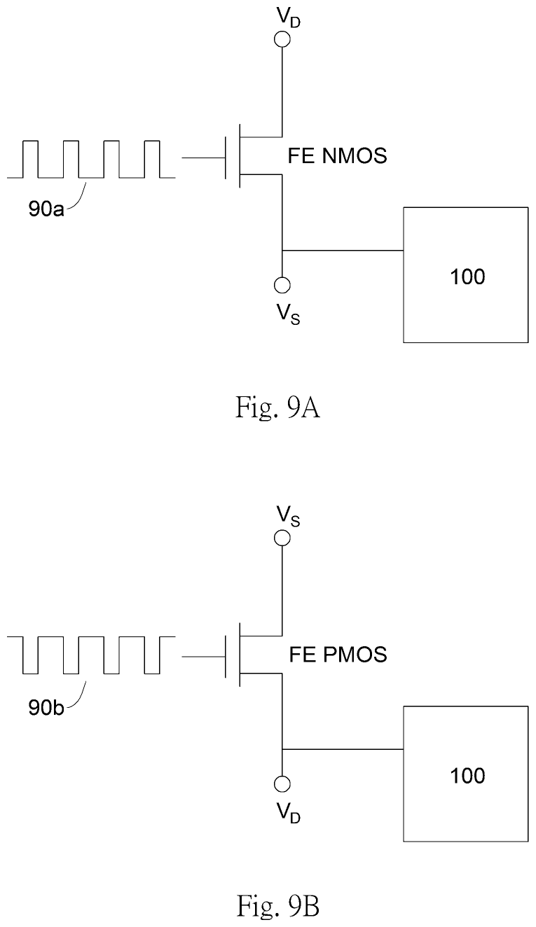

Please refer to FIG. 9A, which shows an application of the FE NMOS anti-fuse device. The FE NMOS anti-device is electrically connected to the repair circuit 100. A pulse generator 90a sends a plurality of voltage pulse, for example having an amplitude of 1.5V, and applied to the gate electrode 25 of the FE NMOS anti-fuse device for programming the FE NMOS anti-fuse device. After the programming operation, the FE NMOS anti-fuse device will much easily turn on as the threshold voltage (V_{T}) decreases even the operating voltage applied to the gate electrode 25 is zero bias.

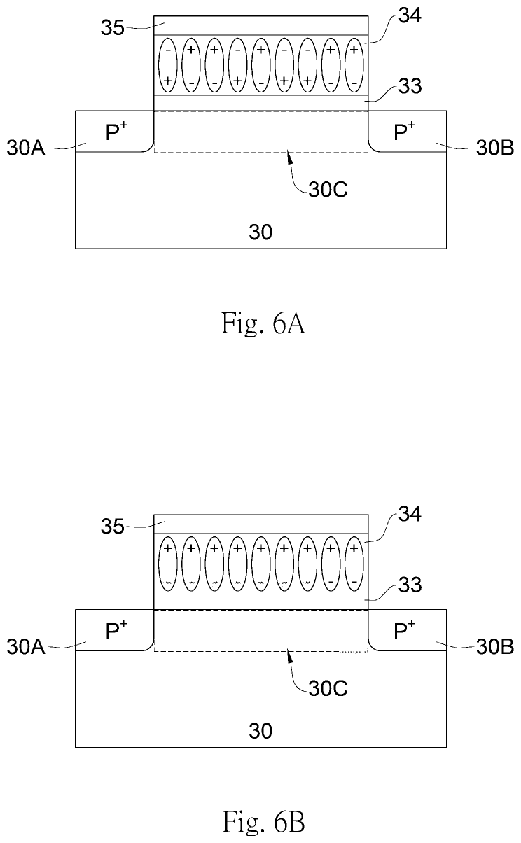

The anti-fuse device by ferroelectric characteristic of the present invention may be configured as a ferroelectric PMOS (FE PMOS) structure according to another embodiment of the present invention, as shown in FIG. 6A and FIG. 6B. Hereinafter, the anti-fuse device is called the FE PMOS anti-fuse device, which comprises an active area 30 and a gate structure formed on the active area 30. The active area 30 has a source region 30A, a drain region 30B laterally spaced from the source region 30A and a channel 30C between the source region 30A and drain region 30B. The source and drain regions 30A, 30B are heavily doped with a P-type material. The gate structure has a ferroelectric layer 34 formed on the channel 30C and a gate electrode 35 formed on the ferroelectric layer 34. The gate structure further has an interfacial layer 33 sandwiched between the ferroelectric layer 34 and the channel 30C. In an implementation of the present invention, the gate electrode 35 may be a metal gate electrode due to the high dielectric constant of the ferroelectric layer 34, and the active area 30 may be a lightly doped well. The interfacial layer 33 may serve as a buffer layer to ease the formation of the ferroelectric layer 34 on the active area 30.

As shown in FIG. 6A, the ferroelectric layer 34 has random dipole directions without any voltage bias. After negative pulse amplitudes giving at the gate electrode 35, for example a negative pulse voltage of −1.5V is applied to the gate electrode 35, and the source/drain regions 30A, 30B are grounded, positive dipoles in the ferroelectric layer 34 turn directions toward the gate electrode 35 owing to negative bias from the gate electrode 35, whereas negative dipoles in the ferroelectric layer 34 turn directions toward the channel 30C. And, the directions of all the dipoles in the ferroelectric layer 34 become consistent and stable, as shown in FIG. 6B.

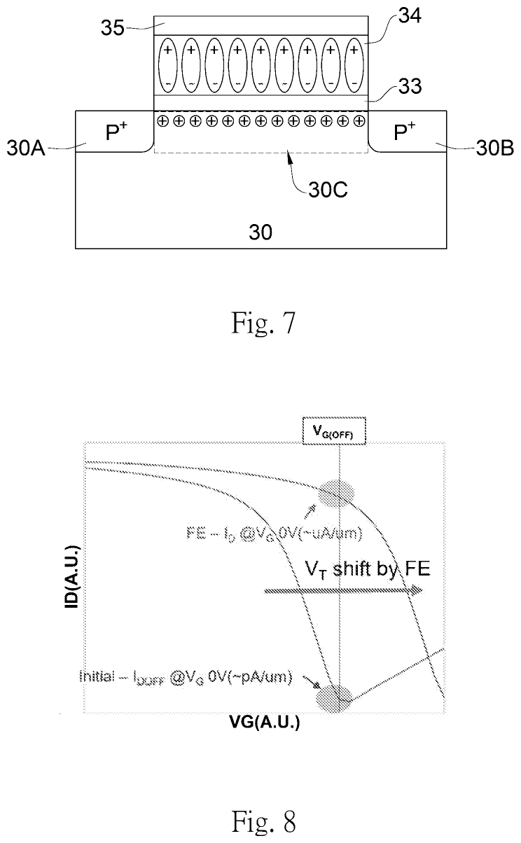

Please refer to FIG. 7, after giving the negative gate pulse voltage to the FE PMOS anti-fuse device, the dipoles in the ferroelectric layer 34 become stable and align in the consistent and constant direction, as such causing a permanent electric field polarization in the ferroelectric layer 34. A conduction path along the channel 30C is thus induced. So, the FE PMOS anti-fuse device turns on much easily as V_{T} (threshold voltage) decreases, even the gate electrode 35 is applied zero bias voltage.

FIG. 8 shows a diagram of drain current (ID) vs. gate voltage (VG) for the FE PMOS anti-fuse device of the present invention after the programming operation compared to the conventional PMOS anti-fuse device performed by the gate oxide breakdown method. The FE PMOS anti-fuse device of the present invention has a high drain current (I_{D}) even at a zero bias gate voltage (V_{G}˜0V).

Please refer to FIG. 9B, which shows an application of the FE PMOS anti-fuse device. The FE PMOS anti-device is electrically connected to the repair circuit 100. A pulse generator 90b sends a plurality of voltage pulse, for example having an amplitude of −1.5V, and applied to the gate electrode 35 of the FE PMOS anti-fuse device for programming the FE PMOS anti-fuse device. After the programming operation, the FE PMOS anti-fuse device will much easily turn on as the threshold voltage (V_{T}) decreases even the operating voltage applied to the gate electrode 35 is zero bias.

The above-mentioned embodiments of the present invention are exemplary and not intended to limit the scope of the present invention. Various variation or modifications made without departing from the spirit of the present invention and achieving equivalent effects shall fall within the scope of claims of the present invention.

What is claimed is:

1. An anti-fuse device by ferroelectric characteristic, comprising:
an active area including a source region, a drain region laterally spaced from the source region and a channel between the source region and drain region; and
a gate structure including a ferroelectric layer formed on the channel and a gate electrode formed on the ferroelectric layer;
wherein a programming operation of the anti-fuse device is performed by application of power to the gate electrode and at least one of the source region and drain region to cause a permanent electric field polarization in the ferroelectric layer to induce a conduction path along the channel.

2. The anti-fuse device as recited in claim 1, wherein the gate electrode is a metal gate electrode.

3. The anti-fuse device as recited in claim 1, wherein the active area is a lightly doped well.

4. The anti-fuse device as recited in claim 1, wherein the gate structure further comprises an interfacial layer sandwiched between the ferroelectric layer and the channel.

5. The anti-fuse device as recited in claim 4, wherein the interfacial layer is a buffer layer.

6. The anti-fuse device as recited in claim 1, wherein the source and drain regions are heavily doped with an N-type material.

7. The anti-fuse device as recited in claim 1, wherein the source and drain regions are heavily doped with a P-type material.

8. The anti-fuse device as recited in claim 6, wherein the programming operation of the anti-fuse device is performed by applying positive voltage pulses at the gate electrode with the source and drain region grounded.

9. The anti-fuse device as recited in claim 8, wherein the positive voltage pulse is 1.5 V voltage pulse.

10. The anti-fuse device as recited in claim 7, wherein the programming operation of the anti-fuse device is performed by applying negative voltage pulses at the gate electrode with the source and drain region grounded.

11. The anti-fuse device as recited in claim 10, wherein the negative voltage pulse is −1.5 V voltage pulse.
